(19) United States
(12) Patent Application Publication
(10) Pub. No.: US 2026/0223724 A1
(43) Pub. Date: Jul. 30, 2026

(54) STACKED SEMICONDUCTOR DIE AND METHODS OF MAKING THE SAME

(71) Applicant: Advanced Micro Devices, Inc., Santa Clara, CA (US)

(72) Inventors: Hsiang-Wei Liu, Hsinchu (TW); Liwei Wang, Austin, TX (US)

(73) Assignee: Advanced Micro Devices, Inc., Santa Clara, CA (US)

(21) Appl. No.: 18/984,321

(22) Filed: Dec. 17, 2024

(51) Int. Cl. H01L 23/31; C23C 16/50; H01L 21/56; H01L 23/00

(52) U.S. Cl. CPC H10W 74/141; C23C 16/50; H10W 74/01; H10W 72/0198

(57) ABSTRACT

A process of making a stacked semiconductor die can include a step of forming a conformal film of insulating material on one or more surfaces of a singulated semiconductor die. In some examples, the presence of the film tends to reduce the formation of cracks during the die stacking process.

### BACKGROUND

The process of fabricating integrated circuits generally involves processing a semiconductor wafer to form multiple die, such that each die on the wafer contains an instance of the same integrated circuit. The processing steps applied to the wafer can vary depending on many factors, including the semiconductor material of the wafer and the function of the integrated circuit (e.g., processing device, memory chip, etc.) being produced. Such processing steps can include photolithography, etching, depositing, oxidizing, etc. The wafer can be cut to separate (e.g., “singulate”) the individual die from each other, and the singulated die can be individually packaged or assembled with other components to form more complex devices. In some cases, the assembly of the device includes a die stacking process, in which two or more singulated die are stacked on each other and bonded together.

### BRIEF DESCRIPTION OF THE FIGURES

The accompanying drawings illustrate a number of example implementations and are a part of the specification. Together with the following description, these drawings demonstrate and explain various principles of the present disclosure.

FIG. 1 is a block diagram of an example computer system in which at least one component includes an example of stacked die.

FIG. 2 is a block diagram showing a side profile of a two adjacent semiconductor die on a carrier, according to an example.

FIG. 3 is a block diagram showing a side profile of the die of FIG. 2 coated by a conformal film of insulating material, according to an example.

FIG. 4 is a block diagram showing a side profile of the coated die of FIG. 3 with a layer of insulating material on and/or surrounding the conformal layer of insulating material, according to an example.

FIG. 5 is a block diagram showing a side profile of the die of FIG. 4 with a surface of the die exposed, according to an example.

FIG. 6 is a block diagram showing a side profile of FIG. 5 in alignment with a second carrier with second die bonded to the additional carrier.

FIG. 7 is a block diagram showing a side profile of two stacked die, each including a die of FIG. 5 and a second die of FIG. 6 stacked on and bonded thereto, according to an example.

FIG. 8 is a block diagram showing a side profile of the stacked die of FIG. 7 with a layer of insulating material on and/or surrounding sides of the die, according to an example.

FIG. 9 is a block diagram showing a side profile of the stacked die of FIG. 7 with a conformal film of insulating material covering surfaces of each second die and a layer of insulating material on and/or surrounding the conformal film of insulating material, according to an example.

FIG. 10 is a block diagram showing a side profile of the stacked die of FIG. 9 with conductive bumps formed on a bottom surface of each stacked die, according to an example.

FIG. 11 is a block diagram showing a side profile of a stacked die of FIG. 10 after singulation, according to an example.

FIG. 12 shows a perspective view of a semiconductor die and a carrier during a plasma deposition step, according to an example.

FIG. 13A shows a flowchart of a die stacking method, according to an example.

FIG. 13B shows a flowchart of a method of preparing die for die stacking, according to an example.

Throughout the drawings, identical reference characters and descriptions indicate similar, but not necessarily identical, elements. While the examples described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure relates to a process for making stacked semiconductor die. The process can include a step of forming a conforming, insulative film on one or more surfaces of a singulated semiconductor die. Without the conforming film, cracks often form on or at the surface of the die when the die is assembled or packaged with one or more other die to form a more complex device. In some examples, the presence of the film tends to reduce the formation of such cracks, thereby improving the yield of the manufacturing process and the reliability of the manufactured devices.

During production of stacked die, a first wafer bonded to a first carrier can be cut, or singulated, yielding a first carrier with many individual die D1 bonded to its surface and gaps between the die D1. These gaps can be referred to as a scribeline area or die-to-die space. Likewise, a second carrier with many singulated die D2 bonded to its surface can be obtained. Ultimately, stacked die can be formed by bonding each of the die D1 to a corresponding die D2. The most efficient way to form the stacked die devices is to simultaneously bond each die D1 on the first carrier to the corresponding die D2 on the second carrier by aligning and bonding the surfaces of the first and second carriers. To facilitate the formation of a strong and reliable bond between each pair of die (D1/D2), the gaps between the die on each carrier can be filled and the surfaces of the carriers can be planarized before the carriers are aligned and their surfaces are bonded.

One option for filling the gaps between the die is to deposit an insulating material (sometimes referred to as a “gap-fill material”) on the carrier surface, using a process such as chemical vapor deposition (“CVD”). However, the inventors have observed that, when the die are stacked, cracks can form in the gap-fill material, in the die, and at the interface of the gap-fill material and the die. These cracks, which can form due to the stress applied to the die and the gap-fill material during the die stacking process, can cause problems ranging from minor degradation of the performance of the die to irrevocable functional defects. Possible approaches to reducing or preventing the formation of such cracks include constraining the stacking configurations of the die (i.e., requiring the surface area of the face of any die D2 to be smaller than the surface area of the face of the die D1 on which D2 is stacked), and/or increasing the distance between the die on the carrier (e.g., by increasing the distance between the die on the wafer prior to singulation, such as by increasing the amount of material removed during singulation). However, these options limit the possibilities for production, decrease yield (by decreasing the number of die per wafer), and/or increase production costs.

The present disclosure relates to an improved process for making stacked semiconductor die. In some examples, prior to aligning and bonding surfaces of two carriers to form a set of stacked die, a conforming film of insulating material (sometimes referred to as a “protection layer”) is formed on one or more surfaces (e.g., sides) of the die on at least one of the carriers. In some examples, the protection layer has strong adhesion to the die and reduces the formation of cracks at the surface of the die during die stacking. In some examples, the protection layer is applied to the die using plasma enhanced chemical vapor deposition (“PECVD”).

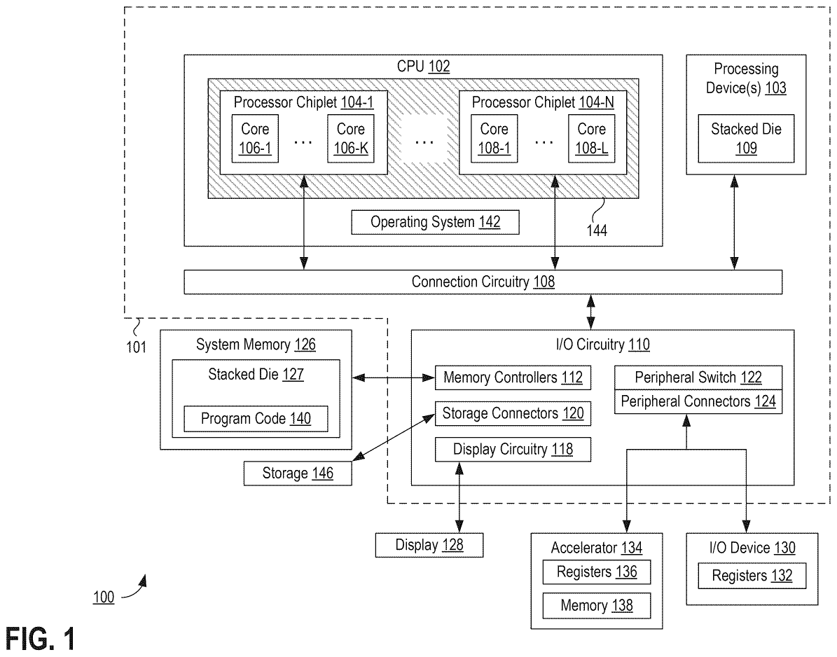

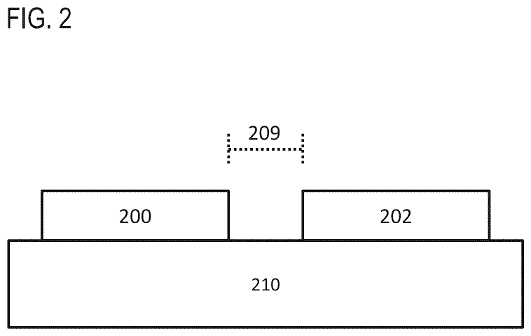

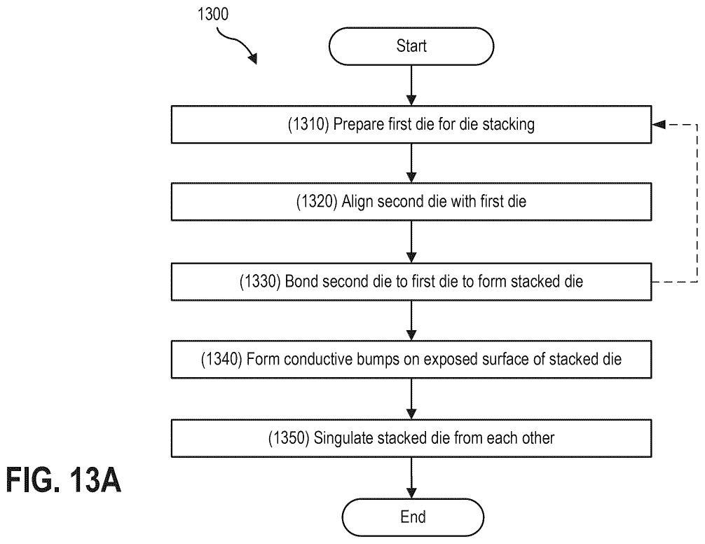

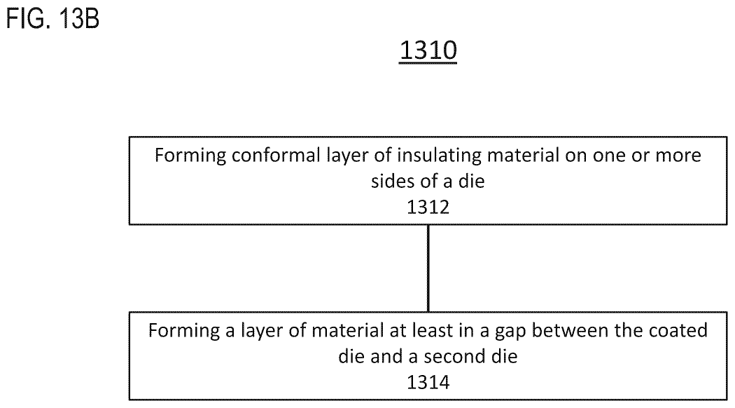

This disclosure provides, with reference to FIG. 1, an example of a computer system including one or more stacked die assembled in accordance with the techniques described herein. FIGS. 2-12 illustrate examples of steps in processes of assembling stacked die. A detailed description of an example of a method for producing stacked die with a protection layer is provided in connection with FIGS. 13A-B.

In some aspects, the techniques described herein relate to a stacked die including: a first die; a conformal film of insulating material on one or more sides of the first die; a layer of insulating material on and/or surrounding the conformal film of insulating material; and a second die bonded to the first die.

In some aspects, the techniques described herein relate to a stacked die, further including conductive bumps on a surface of the first die, wherein the surface of the first die is substantially orthogonal to respective surfaces of the one or more sides of the first die.

In some aspects, the techniques described herein relate to a stacked die, wherein the conformal film is a first conformal film, and the layer of insulating material is a first layer of insulating material, the stacked die further including a second conformal film of insulating material on one or more sides of the second die.

In some aspects, the techniques described herein relate to a stacked die, further including a second layer of insulating material on and/or surrounding the second conformal film wherein the first and second conformal films of insulating material are substantially free of cracks.

In some aspects, the techniques described herein relate to a stacked die, wherein a surface of the first die bonded to a surface of the second die has a first surface area, the surface of the second die bonded to the first die has a second surface area, and the second surface area is greater than the first surface area.

In some aspects, the techniques described herein relate to a stacked die, wherein the first die has a thickness of from 10 to 100 micrometers.

In some aspects, the techniques described herein relate to a stacked die, wherein the conformal film of insulating material has a thickness of from 0.1 to 10 micrometers.

In some aspects, the techniques described herein relate to a stacked die, wherein the conformal film of insulating material includes silicon dioxide, silicon nitride, silicon oxynitride, and/or silicon carbon nitride.

In some aspects, the techniques described herein relate to a stacked die, further including a wafer, wherein the die is a first die, wherein the first die and a second die are formed in the wafer, and wherein a distance between the first die and the second die is from 50 to 300 micrometers.

In some aspects, the techniques described herein relate to a method of assembling a stacked die including: forming a conformal film of insulating material on one or more sides of a first die, thereby creating a coated die; forming a layer of material at least in a gap between the coated die and a second die; and performing a die stacking operating involving the coated die.

In some aspects, the techniques described herein relate to a method, wherein the first die is a first singulated die, the second die is a second singulated die, and forming the conformal film of insulating material on one or more sides of the first die includes forming the conformal film of insulating material on one or more sides of the first singulated die.

In some aspects, the techniques described herein relate to a method, wherein the conformal film of insulating material is formed on the one or more sides of the first die via a plasma deposition process.

In some aspects, the techniques described herein relate to a method, wherein forming the conformal film via the plasma deposition process includes exposing the first die to a plasma of one or more gases including O2, N2, or NH3.

In some aspects, the techniques described herein relate to a method, wherein forming the conformal film of insulating material on the one or more sides of the first die includes forming the conformal film of insulating material on at least two opposing sides of the first die via the plasma deposition process.

In some aspects, the techniques described herein relate to a method, wherein forming the conformal film of insulating material on the one or more sides of the first die includes: during the plasma deposition process, controlling a flow direction of a plasma relative to respective surfaces of the opposing sides of the first die.

In some aspects, the techniques described herein relate to a method, wherein forming the layer of material at least in the gap between the coated die and the second die includes forming a first portion of the layer of material in the gap and forming a second portion of the layer of material on a surface of the coated die, and wherein the method further includes removing at least a portion of the conformal film of insulating material and the second portion of the layer of material from the surface of the coated die, thereby exposing the surface of the coated die.

In some aspects, the techniques described herein relate to a method, wherein performing the die stacking operation includes bonding a third die to the exposed surface of the coated die.

In some aspects, the techniques described herein relate to a method, wherein the coated die and the second die are bonded to a surface of a first carrier, and wherein performing the die stacking operation includes: aligning a surface of a second carrier with respect to the surface of the first carrier; and bonding the aligned surfaces of the first and second carriers, wherein a third die is bonded to the surface of the second carrier, and wherein bonding the aligned surfaces of the first and second carriers includes bonding the third die to the exposed surface of the coated die.

In some aspects, the techniques described herein relate to a method, further including singulating a stacked die including the coated die and the third die.

In some aspects, the techniques described herein relate to a method, including forming conductive bumps on a surface of the coated die.

In some aspects, the techniques described herein relate to a method, wherein the removing at least the portion of the conformal film of insulating material and the second portion of the layer of material from the surface of the coated die includes removing via chemical mechanical polishing.

In some aspects, the techniques described herein relate to a method, wherein the conformal film of insulating material includes silicon dioxide, silicon nitride, silicon oxynitride, silicon carbon nitride, or gallium arsenide.

In some aspects, the techniques described herein relate to a method, wherein the layer of material is formed at least in the gap via chemical vapor deposition.

In some aspects, the techniques described herein relate to a method, wherein forming the layer of material at least in the gap between the coated die and the second die includes forming the layer of material on and/or surrounding the conformal film of insulating material.

In some aspects, the techniques described herein relate to a computer system including: a printed circuit board; a stacked die disposed on the printed circuit board, the stacked die including: a first die; a conformal film of insulating material on one or more sides of the first die; a layer of insulating material on and/or surrounding the conformal film of insulating material; and a second die bonded to the first die; and an integrated circuit disposed on the printed circuit board, wherein the stacked die and the integrated circuit are communicatively coupled via the printed circuit board.

In some aspects, the techniques described herein relate to a system, further including at least one memory storing one or more instructions and/or at least one processor configured to execute the one or more instructions to cause a computer system to perform one or more operations, wherein the at least one memory or the at least one processor includes the stacked die.

FIG. 1 illustrates one exemplary implementation of a computer system 100 configured to implement the techniques described herein, although others are possible. It should be appreciated that FIG. 1 is intended neither to be a depiction of necessary components for a computer system 100 to operate in accordance with the principles described herein, nor a comprehensive depiction.

Computer system 100 can be, for example, a desktop computer, a video game console, a server, a wireless access point or other networking element, a mobile computing device (e.g., laptop computers, tablets, smartphones, smartwatches, implantable health monitoring devices, wearable computers, personal digital assistants, etc.), or any other suitable computing system. Computer system 100 can comprise at least one central processing unit (CPU) 102, one or more processing devices 103 (e.g., graphics processing unit (GPU), accelerated processing unit (APU), vision processing unit (VPU), tensor processing unit (TPU), physics processing unit (PPU), digital signal processing (DSP) circuit, field programmable gate array (FPGA), application-specific integrated circuit (ASIC), etc.), connection circuitry 108, I/O circuitry 110, system memory 126, at least one I/O device 130, at least one accelerator 134, storage 146 (e.g., computer-readable storage media), and/or at least one display 128. In some examples, the CPU 102, processing device(s) 103, connection circuitry 108, and I/O circuitry 110, are coupled to (e.g., mounted on) a printed circuit board (e.g., motherboard) 101. A processing device 103 can include a stacked die 109. Additionally or alternatively, the system memory 126 can include a stacked die 127. The stacked die (109, 127) can be assembled in accordance with the present disclosure. Each of the stacked die can include at least one die having a conformal film of insulating material on one or more sides of the die.

In some examples, a stacked die (109, 127) can be or be a component of a central processing unit (CPU), a core of a CPU, graphics processing units (GPU), a core of a GPU, an accelerated processing unit (APU), a core of an APU, or a memory device. In some examples, a processing device 103 or the system memory 126 can include one or more chiplets, and at least one of the chiplets can include a stacked die (109, 127).

CPU 102 enables processing of data and execution of instructions. The data and instructions can be stored on system memory 126, storage 146, and/or internal memory (not shown) of the CPU 102. In some examples, the CPU 102 includes one or more processor chiplets 104-1 . . . 104-N, which can be disposed on or over a package substrate 144. In some examples, the processor chiplets 104 can communicate with each other via interconnects routed through or on the package substrate 144 (e.g., through an interposer layer disposed between the package substrate 144 and the processor chiplets 104). In some examples, each processor chiplet 104 includes one or more cores (106, 108). Different processor chiplets 104 can have the same or different numbers of cores (106, 108). In the example of FIG. 1, processor chiplet 104-1 has K cores 106-1, 106-2, . . . 106-K, and processor chiplet 104-N has L cores (108-1, 108-2, . . . 108-L). The cores within an individual processor chiplet (e.g., cores 106-1, 106-2, . . . 106-K) can be homogeneous or heterogeneous. Likewise, the cores on different processor chiplets (e.g., cores 106-1 and 108-1) can be homogeneous or heterogeneous.

In the example of FIG. 1, the CPU 102 is configured to execute instructions of an operating system 142 and/or instructions (e.g., program code 140) of one or more applications. In some examples, the functionality of the program code can be implemented by one or more processing devices 103, one or more CPUs 102, one or more processor chiplets of a CPU 102, and/or one or more cores of a processor chiplet.

The data and instructions stored on any of the computer-readable storage media (e.g., system memory 126, storage 146, accelerator memory 138, internal or external caches of the CPU 102, etc.) can comprise computer-executable instructions implementing any suitable functionality.

In some examples, connection circuitry 108 communicatively couples CPUs 102 with each other, with processing device(s) 103, and/or with external caches (e.g., level-2 (L2) cache, level-3 (L3) cache, etc.). Additionally or alternatively, the connection circuitry 108 can communicatively couple the CPUs 102 with I/O circuitry 110, which communicatively couples system memory, storage devices, and peripheral devices to each other and (via the connection circuitry 108) to the CPUs 102. The connection circuitry can couple the CPUs 102, external caches, and I/O circuitry 110 using any suitable network topology (e.g., a front-side bus, a back-side bus, etc.), and the coupled components can send and receive messages via the connection circuitry using any suitable communication protocol. In some examples, portions of the connection circuitry 108 can be integrated into the CPU(s) 102 and/or processing device(s) 103.

In some examples, I/O circuitry 110 includes one or more memory controllers 112, one or more storage connectors 120, display circuitry 118, one or more peripheral connectors 124, and a peripheral switch 122. The memory controller(s) 112 can be configured to control the flow of data to and from the system memory 126. The storage connector(s) 120 can be configured to control the flow of data to and from the storage 146. The display circuitry 118 can be configured to send visual data (e.g., user interface data, image data, video data, etc.) to the display 128, which can be configured to display the visual data. In some examples, the display circuitry 118 can also be configured to receive data representing user input from the display 128 (e.g., in cases where the display 128 includes a touchscreen). In some examples, portions of the I/O circuitry 110 can be integrated into a motherboard and/or motherboard chipset (e.g., I/O circuitry 110) of the computer system 100.

Each of the peripheral connectors 124 can be configured to physically connect and communicatively couple the I/O circuitry 110 to a peripheral device. Any suitable type of peripheral device can be connected to a peripheral connector 124 including, without limitation, an I/O device 130 (e.g., an input device, output device, or input/output device), an accelerator 134, etc. Some non-limiting examples of an input device can include a mouse, keyboard, scanner, video game controller, microphone, webcam, etc. Some non-limiting examples of an output device can include a display, printer, speakers, headphones, earbuds, etc. Some non-limiting examples of an input/output device can include a storage device (e.g., disk drive, solid-state drive, universal serial bus (USB) flash drive, memory card, tape drive, etc.), a networking device (e.g., modem, router, gateway, network adapter, access point, etc.), etc. A networking adapter can be any suitable hardware and/or software to enable the computer system 100 to communicate via wires and/or wirelessly with any other suitable computing system over any suitable computing network. The computing network can include wireless access points, switches, routers, gateways, and/or other networking equipment as well as any suitable wired and/or wireless communication medium or media for exchanging data between two or more computers, including the Internet. Optionally, an I/O device can include one or more registers 132. In some examples, the I/O circuitry 110 can control the operation of an I/O device 130 by writing suitable data to one or more of the I/O device's registers, and/or can monitor the status of an I/O device 130 by reading the contents of one or more of the I/O device's registers.

Some non-limiting examples of an accelerator 134 can include a graphics processing unit (GPU), accelerated processing unit (APU), vision processing unit (VPU), tensor processing unit (TPU), physics processing unit (PPU), digital signal processing (DSP) circuit, field programmable gate array (FPGA), application-specific integrated circuit (ASIC), etc. In some examples, an accelerator 134 includes one or more registers 136 and memory 138. In some examples, the I/O circuitry 110 can control the operation of an accelerator 134 by writing suitable data to one or more of the accelerator's registers, and/or can monitor the status of an accelerator 134 by reading the contents of one or more of the accelerator's registers.

The peripheral switch 122 can be configured to switch packets sent to or from the peripheral devices. Any suitable type of peripheral connector(s) 124 and peripheral switch 122 can be used including, without limitation, universal serial bus (e.g., USB-A, USB-B, USB-C, USB-3.0, etc.), Ethernet, DisplayPort, high-definition multimedia interface (HDMI), peripheral component interconnect (PCI), peripheral component interconnect eXtended (PCI-X), peripheral component interconnect express (PCIe), accelerated graphics port (AGP), etc.

As described above computer system 100 can have one or more components and peripherals, including input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computing device can receive input information through speech recognition or in other audible format.

FIGS. 2-12 illustrate an example process for the manufacturing of stacked die. Stacked die can include at least two die bonded to one another. In some examples, stacked die can include at least one die with a conformal film of insulating material on at least one side of the die. In some examples, there can be an additional layer of insulating material on at least one side of the conformal film of insulating material and/or on at least one side of a die.

FIG. 2 illustrates one exemplary configuration of a carrier 210 with two adjacent die (200, 202) on the carrier 210. The die (200, 202) can have a space therebetween 209 (sometimes referred to as the “die-to-die space”). FIG. 2 and subsequent figures illustrate two exemplary die (200, 202) at various steps in a die stacking process. For brevity, the steps illustrated in FIGS. 2-12 are generally described as being applied to an example die 200. However, one or ordinary skill will appreciate that the steps illustrated in FIGS. 2-12 can be simultaneously applied to one or more (e.g., all) die disposed on a carrier, and that the number of die disposed on a carrier can range from one to tens, hundreds, thousands, or more.

In some examples, the die-to-die space 209 is from 50 to 1,000 μm (i.e., micrometers) (e.g., from 70 to 250 μm). However, as noted above, if the die-to-die space is too small, when die are stacked, cracking can occur in the gap-fill material, in the die, and at the interface of the gap-fill material and the die. Stacked die made according to the present disclosure can have a smaller die-to-die space while being substantially crack free. In some examples, the die-to-die space for stacked die according to the present disclosure can be from 50 to 300 μm and the die, the protection layer, the gap-fill material, and the interface of the protection layer and the die exhibit no cracking or substantially no cracking (e.g., the stacked die are substantially free of cracks).

In some examples, the one or more die (200, 202) have been singulated from a wafer. Singulation can include removing at least some of the material of the wafer by cutting (e.g., with a diamond blade), laser removal, plasma removal, and/or other methods of removing at least some wafer material between adjacent die. In some examples, the wafer is bonded to the carrier 210 after the die (200, 202) have been formed in the wafer but before the wafer has been singulated. In some examples, the carrier 210 is a high-quality glass, plastic, ceramic material suitable for a cleanroom environment. In some examples, the wafer comprises silicon (Si), silicon germanium (SiGe), sapphire, gallium arsenide (GaAs), gallium nitride (GaN), silicon carbide (SiC), indium phosphide (InP), or any other material suitable for the fabrication of integrated circuits. In some examples, the outer surface of the carrier 210 comprises a barrier layer. The barrier layer can prevent certain chemicals from adhering to the carrier.

In some examples, the sides of the die 200 comprise silicon, gallium-arsenide (GaAs), gallium nitride (GaN), indium-gallium-arsenide (InGaAs), any other suitable III-V compound, or any other suitable semiconductor material. In some examples, the sides of the die 200 comprise the same material as the surface of the carrier 210. In some examples, the die is an active die, or a dummy die (i.e., a die that does not have semiconductor properties). In some examples, the die can be from 10 to 100 μm thick. In some examples, because of the size of the die 200, the die 200 can be prone to the formation of cracks (e.g., a die that is relatively smaller or relatively larger than another die can be more prone to cracking). In some examples, regardless of the size of the die 200, a die produced according to the present disclosure can be substantially free of cracks.

In some examples, the die includes an integrated circuit (IC). The IC can be or be a component of a central processing unit (CPU), a core of a CPU, a graphics processing unit (GPU), a core of a GPU, an accelerated processing unit (APU), a core of an APU, a memory device, or any other suitable IC. In some examples, the IC can be or be a component of a chiplet (e.g., a chiplet of a processing device or memory).

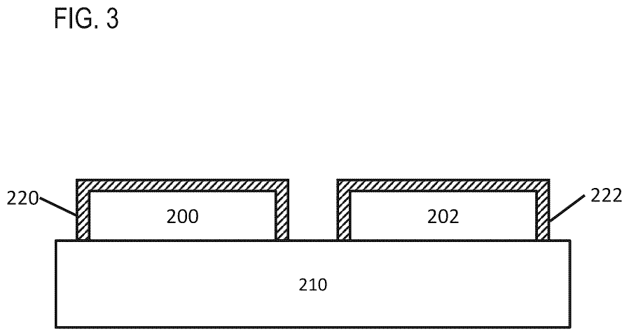

Referring now to FIG. 3, a conformal film of insulating material 220 can be formed on the die 200 of FIG. 2. In some examples, the conformal film is formed using a plasma deposition process (e.g., a plasma enhanced chemical vapor deposition (“PECVD”)). In some examples, the conformal film of insulating material 220 is formed on one or more surfaces (e.g., sides) of the die 200. In the exemplary configuration of FIG. 3, the conformal film of insulating material 220 is on all sides of the die 200. In some examples, the conformal film of insulating material 220 can cover a substantial portion of the surface area of at least one of the sidewalls of the die 200. In some examples, the conformal film of insulating material 220 can be formed on all but the top from 0.1 to 10 μm of the sidewall of the die 200 (e.g., a surface of a die 200 on which a conformal film of insulating material is formed, can be covered by the conformal film of insulating material on all but the top 0.1 to 10 μm of the surface). In some examples, the conformal film of insulating material can be from 0.1 to 10 μm thick.

In some examples (e.g., examples in which the die is silicon-based), the conformal film of insulating material 220 comprises silicon dioxide (SiO₂), silicon nitride (Si₃N₄), silicon carbon nitride (SiCN), silicon oxynitride (Si₂N₂O), and/or any other suitable silicon-based material. In some examples (e.g., examples in which the die is gallium-based), the conformal film of insulating material 220 comprises an oxide or nitride of gallium nitride (GaN), gallium-arsenide (GaAs), indium-gallium-arsenide (InGaAs), and/or any other suitable gallium-based materials. The composition of the conformal film of insulating material 220 can vary based on the chemical(s) that are used in the plasma deposition process (e.g., a PECVD process). In some examples, a chemical is emitted from a plasma emitter during the plasma deposition (e.g., PECVD). In some examples, the chemical(s) emitted from the plasma emitter comprise oxygen (O₂), nitrogen (N₂), ammonia (NH₃), and/or combinations thereof. In some examples, the chemical(s) emitted from the plasma emitter are in the gas phase. The chemicals emitted from the plasma emitter favorably have strong adhesion to the outer surface of the die 200. In some examples, the chemicals emitted from the plasma emitter react with the chemical(s) on the outer surface of the die 200, thereby forming a stable structure on the surface of the die 200. In some examples, oxygen is emitted from a plasma emitter and reacts with the material on the surface of the die 200 that comprises silicon, and, because of the reaction, a conformal film of insulating material 220 comprising silicon dioxide (SiO₂) is formed. In some examples, the conformal film of insulating material can be formed on the die 200 using a chemical vapor deposition process (“CVD”) process or a plasma vapor deposition (“PVD”) process. In some examples, the conformal film of insulating material is not formed on the carrier 210 at least because of the barrier layer of the carrier 210.

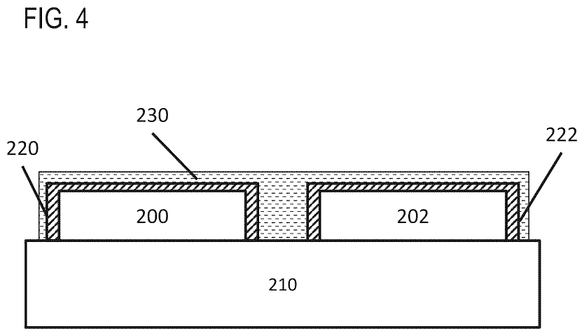

Referring now to FIG. 4, a layer of insulating material (sometimes referred to as a “gap-fill material”) 230 can be formed on the conformal film of insulating material 220 and/or on the carrier 210 of FIG. 3. In some examples, the layer of insulating material is formed using a CVD process. In some examples, the layer of insulating material can be formed in the die-to-die space 209 or on a surface of a die 200. In some examples, the insulating material occupies some or all of the die-to-die space 209. In some examples, the insulating material can comprise silicon dioxide (SiO₂), silicon nitride (Si₃N₄), silicon oxynitride (Si₂N₂O), silicon carbon nitride (SiCN), and/or any other insulating material.

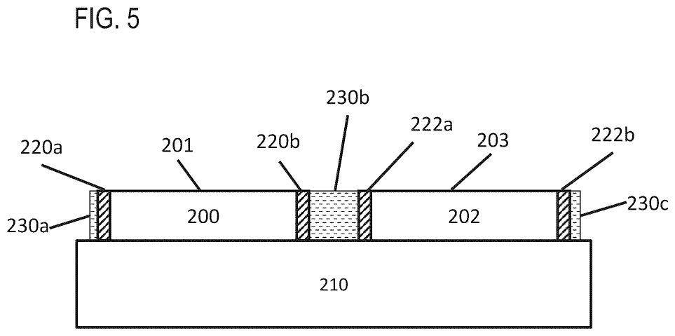

Referring now to FIG. 5 a surface of the die 200 of FIG. 4 can be exposed by a planarization process, creating an exposed surface (201, 203) of the die (200, 202). In some examples, the planarization process includes chemical mechanical planarization or chemical mechanical polishing. The planarization process can remove at least some of the conformal film of insulating material 220 and/or the layer of insulating material 230. The planarization process can create subsections of conformal film of insulating material (220a, 220b, 222a, 222b) and/or subsections of layers of insulating material (230a, 230b, 230c) by removing at least some material (e.g., the conformal film of insulating material and/or the insulating material), such that the entire layer of material is no longer contiguous.

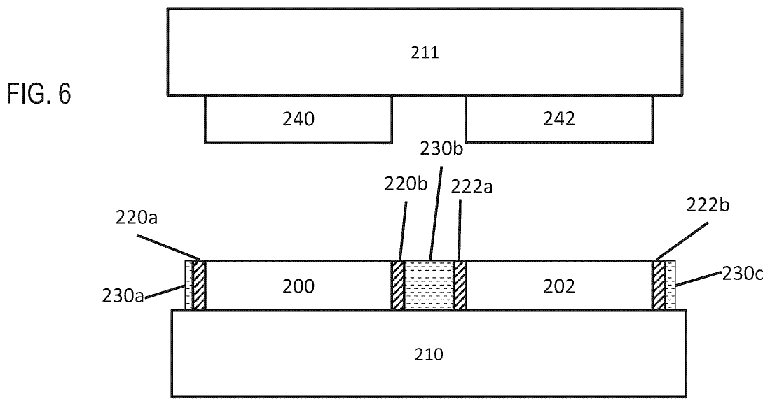

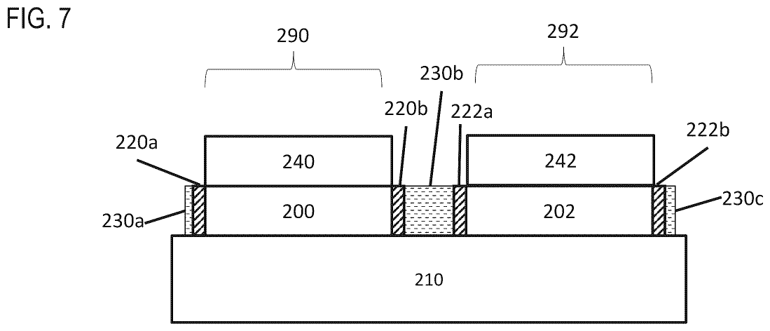

Referring now to FIG. 6, a second carrier 211 can be aligned with the carrier 210 of FIG. 5. In some examples, one or more second die (240, 242) can be bonded to the second carrier 211. In some examples the second carrier 211 is aligned to the carrier 210 by aligning the die (200, 202) on the carrier 210 with the second die (240, 242) on the second carrier 211. In some examples, the carrier 210 is aligned with the second carrier 211 by aligning a plurality of die on the carrier 210 with a plurality of second die on the second carrier 211. When the carrier 210 and the second carrier 211 are aligned, the one or more second die (240, 242) of the second carrier 211 can be bonded to the die (200, 202) of the carrier 210, thereby creating stacked die on the carrier 210, as shown in FIG. 7. As is also shown in FIG. 7, the second carrier 211 can be removed from the one or more second die (240, 242) after the one or more second die (240, 242) are bonded to the die (200, 202).

Referring now to FIG. 7, one or more second die (240, 242) can be bonded to the die (200, 202) of FIG. 6, thereby created stacked die (290, 292). The bonding process can include solder bonding, mechanical coupling, adhesive bonding, wire bonding, and/or other suitable bonding methods. In some examples, the one or more second die 240 can be bonded to the die 200 on the exposed surface 201 of the die 200. In some examples, the one or more of second die 240 can be dummy die, active die, and/or combinations thereof. In some examples, each of the one or more second die 240 can have a thickness of from 10 to 100 μm. In some examples, the second die 240 includes an integrated circuit (IC). The IC can be or be a component of a central processing unit (CPU), a core of a CPU, a graphics processing unit (GPU), a core of a GPU, an accelerated processing unit (APU), a core of an APU, a memory device, or any other suitable IC. In some examples, the IC can be or be a component of a chiplet (e.g., a chiplet of a processing device or memory).

In some examples, to prevent cracking of the die 200, the surface area of the face of the die 200 that is bonded to the second die 240 is larger (e.g., greater) than the surface area of the face of the second die 240 that is bonded to the die 200. However, in some examples, at least because of the conformal film of insulating material 220 on the one or more sides of the die 200 or the one or more sides of the second die 240, the die 200 and the second die 240 can have increased resistance to cracking (e.g., can be substantially free of cracks) regardless of the size of the respective surface areas of the die 200 and the second die 240. That is, because of the increased resistance to cracking due to the conformal film of insulating material, the relative dimensions of the die 200 and the second die 240 can be varied while reducing the propensity of cracking. In some examples, stacked die packaging and assembling can include varying the relative sizes of the stacked die, varying the composition of the stacked die, varying the orientation of the stacked die (e.g., varying which surface of the die is bonded to another die), varying the order of stacking of the die, and varying the number of stacked die, among other variations. In some examples, at least in part because of the forming of conformal film of insulating material on the die, the assembly of the stacked die can vary while the stacked die are crack free or substantially crack free. As explained below, conformal films of insulating material can also be formed on the one or more second die 240 (e.g., before aligning the die (200, 202) of the carrier 210 with the second die (240, 242) of the second carrier 211) to decrease the formation of cracks. In some examples, a particular die and/or a particular side of a die can be susceptible to the formation of cracks during assembly or packaging of stacked die. In some examples, a conformal film of insulating material can be formed on the particular die and/or the one or more sides of a particular die that is particularly susceptible to cracking to reduce or prevent the formation of cracks during die stacking. In some examples, because of the location of the die on the carrier (e.g., near the edge of the carrier, near the center of the carrier, etc.), the die may be particularly susceptible to cracking. In some examples, a conformal film of insulating material can be formed on a die that is particularly susceptible to cracking, at least because of the position of the die on the carrier, to reduce or prevent the formation of cracks in the die.

In some examples, the stacked die 290 includes die 200 and second die 240. More generally, stacked die can include two or more die arranged in a stacked configuration, with adjacent and opposing surfaces of the stacked die bonded to each other. In some examples, an uppermost die of a stacked die assembly may be referred to as the “top die,” and a lowermost die of a stacked die assembly may be referred to as the “bottom die.”

An example has been described in which the second die (240, 242) are aligned with the die (200, 202) in parallel, while the second die (240, 242) are attached to a second carrier 211. In some examples, the second die (240, 242) are individually placed upon and bonded to the exposed surfaces of the respective counterpart die (200, 202), using a pick-and-place technique or any other suitable die-stacking technique. In some examples, FIG. 7 illustrates the state of the stacked die assembly process after alignment and bonding of the die (200, 202) with the second die (240, 242), irrespective of whether the second die (240, 242) are aligned with the die (200, 202) individually or in parallel.

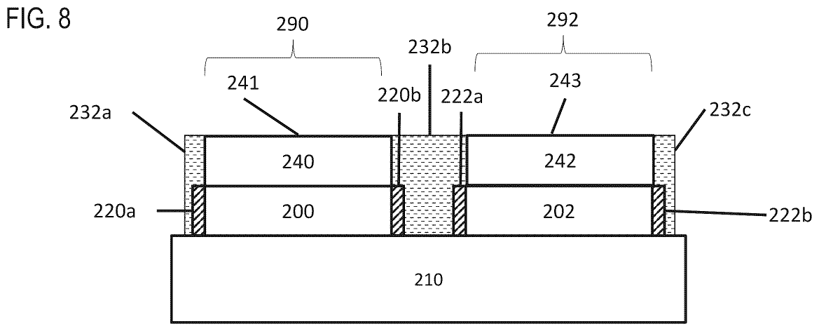

Referring now to FIG. 8, a layer of insulating material 232 (sometimes referred to as a “gap-fill material”) can be formed on the stacked die (290, 292) of FIG. 7. In some examples, the layer of insulating material is formed using CVD. In some examples, the layer of insulating material can be formed in the die-to-die space between the second die (240, 242) and/or on surfaces of the second die. In some examples, a surface of the stacked die (290, 292) of FIG. 7 can be exposed by a planarization process, creating an exposed surface (241, 243) of the stacked die (290, 292). In some examples, the planarization process includes chemical mechanical planarization or chemical mechanical polishing. In some examples, the planarization process can create subsections of insulating material (232a, 232b, 232c) by removing at least some material such that the entire layer of material is no longer contiguous.

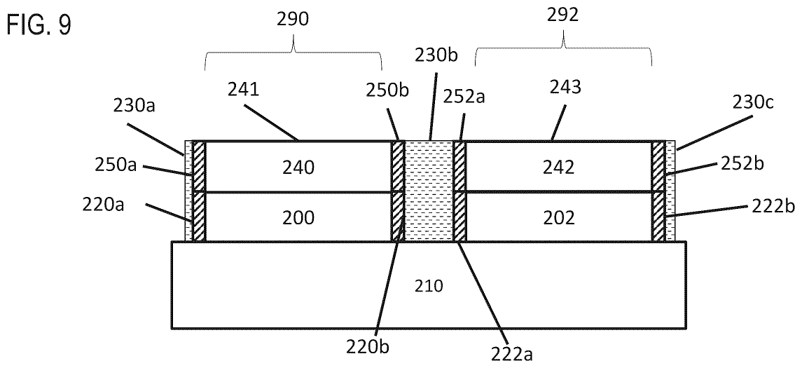

Referring now to FIG. 9, in some examples, a conformal film of insulating material (250, 252) (shown in FIG. 9 in the form of subsections of conformal film of insulating material (250a, 250b, 252a, 252b)) can be formed on the stacked die (290, 292) of FIG. 7, prior to the formation of the layer of insulating material 232 and the planarization process described in connection with FIG. 8. In some examples, the conformal film (250, 252) is formed using a plasma deposition process (e.g., a plasma enhanced chemical vapor deposition (“PECVD”)). In some examples, the conformal film (250, 252) of insulating material is formed on one or more surfaces (e.g., sides) of the second die 200. In some examples, at least some of the conformal film (250, 252) of insulating material can be removed from the second die (240, 242) (e.g., using the planarization process described in connection with FIG. 8), creating subsections of conformal film (250a, 250b, 252a, 252b) of insulating material on the second die (240, 242). In some examples, the conformal film of insulating material (250, 252) can cover a substantial portion of the surface area of at least one of the sidewalls of the second die (240, 242). In some examples, the conformal film (250, 252) of insulating material can be formed on all but the top from 0.1 to 10 μm of the sidewall of the second die (240, 242) (e.g., a surface of a second die 240 on which a conformal film 250 of insulating material is formed can be covered by the conformal film of insulating material on all but the top 0.1 to 10 μm of the surface). In some examples, the conformal film 250 of insulating material can be from 0.1 to 10 μm thick.

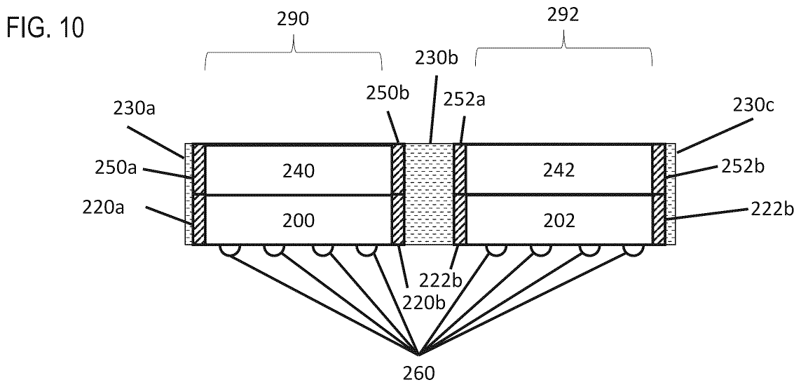

Referring now to FIG. 10, in some examples, the carrier 210 of FIG. 9 can be removed from the stacked die 290 to create an exposed surface of the stacked die 290. In some examples, one or more conductive bumps 260 can be formed on the exposed surface of the stacked die 290. In some examples, the conductive bumps 260 can be formed on the die 200 of the stacked die 290 via coupling and/or soldering. The conductive bumps 260 can assist in coupling the stacked die 290 to other components of a semiconductor device or system. In some examples, the conductive bumps 260 can assist in coupling the stacked die 290 to other die. In some examples, the conductive bumps 260 can be on a side of stacked die 290 that is substantially orthogonal to a side of the stacked die on which the conformal film of insulating material is formed.

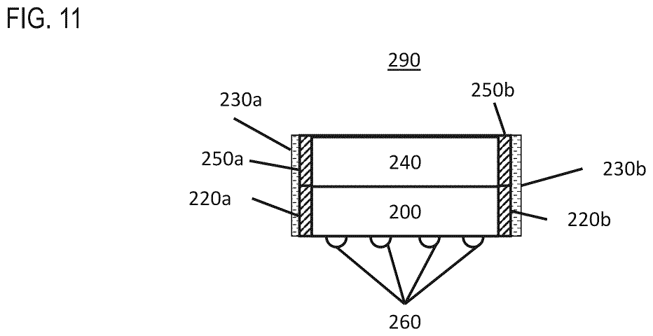

Referring now to FIG. 11, the stacked die 290 can be separated from the other stacked die 292. In some examples, the stacked die can be separated from each other using a singulation process. The stacked die 290 can be used as components of a computer system 100 (e.g., the stacked die(s) (109, 127) of FIG. 1). In some examples, at least some of the conformal film of insulating material (220, 250) and/or the layer of insulating material (230) is on the stacked die 290 while the stacked die 290 is in use in a computer system.

In some examples, the stacked die 290 includes die 200 and second die 240. More generally, stacked die 290 can include two or more die arranged in a stacked configuration, with adjacent and opposing surfaces of the stacked die bonded to each other. In some examples, stacked die 290 further includes one or more materials or structures bonded to or formed on the die 200 and/or on the second die 240 (e.g., conformal film of insulating material (220, 250), layer of insulating material 230, conductive bumps 260, etc.).

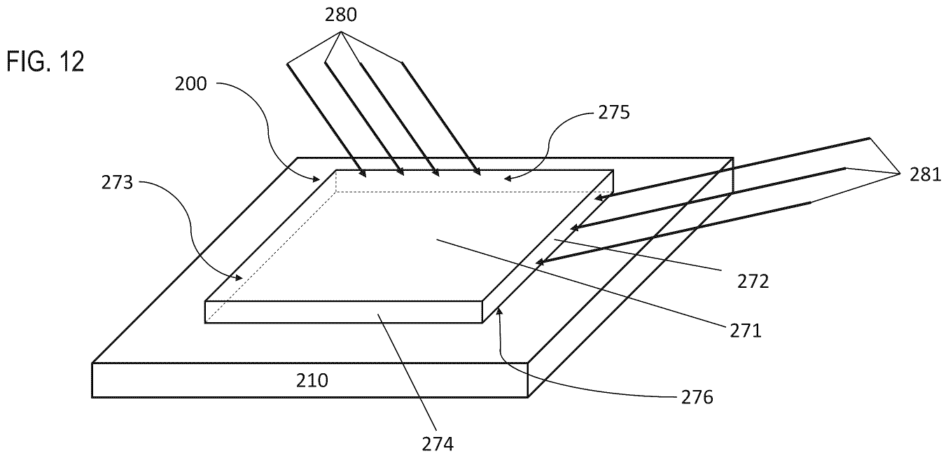

As noted above, the conformal film of insulating material can be formed on one or more sides of a die 200. The one or more sides of the die 200 on which the conformal film of insulating material forms can be selected or adjusted by selecting or changing the direction in which the plasma waves are emitted (e.g., by controlling the flow direction of the plasma) during the plasma deposition process (e.g., PECVD). In some examples, the thickness of the conformal film of insulating material can be adjusted by changing the direction in which and/or the duration of time during which the plasma waves are emitted (e.g., by controlling the flow direction of the plasma and/or the period of time during which the plasma is emitted) during the plasma deposition process (e.g., PECVD). In some examples, the thickness of the conformal film of insulating material on one side of a die may be different than the thickness of the conformal film of insulating material on a different side of a die. In some examples, the thickness of the conformal film of insulating material on one side of a first die may be different than the thickness of the conformal film of insulating material on one side of a second die. In some examples, a conformal film of insulating material may be formed such that it has a uniform thickness on more than one side of a die using a PVD process or a CVD process, among other processes. In some examples, a conformal film of insulating material may be formed such that it has a uniform thickness on more than one die on a single wafer using a PVD or a CVD process, or any other suitable process. Referring now to FIG. 12, the plasma waves (280, 281) can be emitted such that the conformal film of insulating material can be formed on certain sides (e.g., any of sides 271-276) of the die 200. For example, the plasma can be emitted such that the conformal film of insulating material can be formed on the sides that are opposing each other (e.g., side 272 and 273 are opposing sides), or sides that are substantially orthogonal (e.g., side 272 and side 275 are substantially orthogonal). As can be appreciated from FIG. 12, all sides of the die 200 that are not opposing sides are substantially orthogonal to the other sides. More than one side can be selected for forming the conformal film of insulating material. In some examples, the one or more sides of a first die on which the conformal film of insulating material is formed can differ from the one or more sides of a second die on which the conformal film of insulating material is formed.

FIG. 13A shows a flowchart of an example die stacking method 1300. In some examples, the die stacking method 1300 is applied to one or more die on a carrier (e.g., one or more die that were singulated from the same wafer) to form one or more stacked die. In some examples, the die stacking method 1300 includes acts of preparing 1310 first die (e.g., bottom die) for die stacking, aligning 1320 second die (e.g., top die) with the first die, bonding 1330 the second die to the first die to form stacked die, forming 1340 conductive bumps on an exposed surface of the stacked die, and singulating 1350 the stacked die from each other. Some examples of acts 1310-1350 are described in further detail below.

In some examples, the die stacking method includes preparing 1310 one or more first die for die stacking. In some examples, each first die is an individual, singulated die. In some examples, all of the first die have been singulated from the same wafer and are disposed on a carrier. In some examples, preparing the first die for die stacking includes fabricating the first die on a wafer and singulating the first die from the wafer. In some examples, each first die is a stacked die including N die arranged in a stack (N≥2), and the method 1300 is performed to add another die to each stacked die, such that each stacked die includes N+1 die. Some non-limiting examples of first die (e.g., die 200, 202) are described above in connection with FIG. 2.

Referring to FIG. 13B, an act 1310 of preparing first die for die stacking can include an act of forming 1312 a conformal film of insulating material on one or more sides of the first die, thereby creating coated die. In some examples, the conformal film of insulating material is formed on one or more sides of the first die using a chemical vapor deposition process (e.g., a plasma-enhanced chemical vapor deposition process). Some non-limiting examples of forming a conformal film of insulating material (e.g., 220, 222) on first die (e.g., die (200, 202)) are described above in connection with FIGS. 3 and 12.

Still referring to FIG. 13B, an act 1310 of preparing first die for die stacking can further include an act of forming 1314 a layer of material at least in a gap between adjacent coated die. In some examples, the layer of material is formed using a chemical vapor deposition process. In some examples, the layer of material is formed on surfaces of the coated die, in addition to being formed in the gap between adjacent coated die. In some examples, forming the layer of material at least in the gap between adjacent coated die further includes planarizing the coated die. Some non-limiting examples of forming a layer (e.g., layer 230) of material (e.g., insulating material) in a gap between coated die (e.g., die 200, 202) are described above in connection with FIGS. 4-5.

Referring again to FIG. 13A, the die stacking method 1300 can include aligning 1320 second die with the first die. Some non-limiting examples of aligning second die (e.g., die 240, 242) with first die are described above in connection with FIG. 6.

In some examples, the die stacking method 1300 includes bonding 1330 the second die to the first die, thereby forming stacked die including the first and second die. Some non-limiting examples of bonding second die (e.g., die 240, 242) to first die (e.g., die 200, 202) to form stacked die (e.g., die 290, 292) are described above with reference to FIGS. 6-9.

In some examples, acts 1310-1330 are repeated one or more times to stack additional die on the stacked die. For example, after bonding the second die to the first die to form stacked die, the die stacking method can further include acts of preparing 1310 “first die” (e.g., the stacked die 290, 292) for die stacking, aligning “second die” (e.g., any additional die) with the stacked die, and bonding 1330 the additional die to the stacked die (290, 292), thereby forming new stacked die including the previous stacked die (290, 292) and the additional die.

In some examples, the die stacking method 1300 includes forming 1340 conductive bumps on one or more exposed surfaces of the stacked die. Some non-limiting examples of forming conductive bumps (e.g., bumps 260) on exposed surfaces of stacked die (e.g., die 290, 292) are described above in connection with FIG. 10.

In some examples, the die stacking method 1300 includes singulating 1350 the stacked die from each other. Some non-limiting examples of singulating stacked die (e.g., die 290, 292) from each other are described above in connection with FIG. 11. After the stacked die are singulated, they can be used components of a computer system 100, such as stacked die(s) (109, 127) in FIG. 1.

In some examples, performing the die stacking method 1300 yields stacked die that are crack-free or substantially crack-free. In some examples, the stacked die assembled using the die stacking method 1300 are “substantially crack-free” if the ratio of assembled stacked die exhibiting cracks to the total number of assembled stacked die is less than a threshold (e.g., 1-15%). In some examples, the stacked die assembled using the die stacking method 1300 are “substantially crack-free” if the percentage of assembled stacked die deemed defective due to cracks created during the die stacking process is less than a threshold (e.g., 1-15%).

Techniques operating according to the principles described herein can be implemented in any suitable manner. While the foregoing disclosure sets forth various implementations using specific block diagrams, flowcharts, and examples, each block diagram component, flowchart step, operation, and/or component described and/or illustrated herein can be implemented, individually and/or collectively, using a wide range of equipment and/or processing techniques.

Included in the discussion above are flowcharts showing steps and acts of processes that are used to assemble stacked die. It should be appreciated that the flowchart(s) included herein illustrate the functional information one of ordinary skill in the art can use to assemble stacked die using the techniques described herein. It should also be appreciated that, unless otherwise indicated herein, the particular sequence of steps and/or acts described in each flowchart is merely illustrative of the fabrication processes that can be implemented and can be varied in implementations and examples of the principles described herein.

It should be appreciated that some examples can be in the form of a method, of which at least one example has been provided. The acts performed as part of the method can be ordered in any suitable way. Accordingly, examples can be constructed in which acts are performed in an order different than illustrated, which can include performing some acts simultaneously, even though shown as sequential acts in illustrative examples.

Various aspects of the examples described above can be used alone, in combination, or in a variety of arrangements not specifically discussed in the examples described in the foregoing and is therefore not limited in its application to the details and arrangement of components set forth in the foregoing description or illustrated in the drawings. For example, aspects described in one example can be combined in any manner with aspects described in other examples.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

The word “exemplary” or “example” is used herein to mean serving as an example, instance, or illustration. Any embodiment, implementation, process, feature, etc. described herein as exemplary or as an “example” should therefore be understood to be an illustrative example and should not be understood to be a preferred or advantageous example unless otherwise indicated.

The phrase “and/or,” as used in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements can optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one example, to A only (optionally including elements other than B); in another example, to B only (optionally including elements other than A); in yet another example, to both A and B (optionally including other elements); etc.

Unless otherwise noted, the terms “connected to” and “coupled to” (and their derivatives), as used in the specification and claims, are to be construed as permitting both direct and indirect (i.e., via other elements or components) connection.

Unless otherwise noted, a first numeric value is “approximately” equal to a second numeric value if the first numeric value is within ±20%, ±10%, or ±5% of the second numeric value.

Having thus described several aspects of at least one example, it is to be appreciated that various alterations, modifications, and improvements will readily occur to those skilled in the art. Such alterations, modifications, and improvements are intended to be part of this disclosure, and are intended to be within the spirit and scope of the principles described herein. Accordingly, the foregoing description and drawings are by way of example only.

We claim:

1. A stacked die comprising:
a first die;
a conformal film of insulating material on one or more sides of the first die;
a layer of insulating material on and/or surrounding the conformal film of insulating material; and
a second die bonded to the first die.

2. The stacked die of claim 1, further comprising conductive bumps on a surface of the first die, wherein the surface of the first die is substantially orthogonal to respective surfaces of the one or more sides of the first die.

3. The stacked die of claim 1, wherein the conformal film is a first conformal film, and the layer of insulating material is a first layer of insulating material, the stacked die further comprising a second conformal film of insulating material on one or more sides of the second die.

4. The stacked die of claim 3, further comprising a second layer of insulating material on and/or surrounding the second conformal film wherein the first and second conformal films of insulating material are substantially free of cracks.

5. The stacked die of claim 4, wherein a surface of the first die bonded to a surface of the second die has a first surface area, the surface of the second die bonded to the first die has a second surface area, and the second surface area is greater than the first surface area.

6. The stacked die of claim 5, wherein the conformal film of insulating material has a thickness of from 0.1 to 10 micrometers.

7. The stacked die of claim 1, wherein the conformal film of insulating material comprises silicon dioxide, silicon nitride, silicon oxynitride, and/or silicon carbon nitride.

8. The stacked die of claim 1, further comprising a wafer, wherein the die is a first die, wherein the first die and a second die are formed in the wafer, and wherein a distance between the first die and the second die is from 50 to 300 micrometers.

9. A method of assembling a stacked die comprising:
forming a conformal film of insulating material on one or more sides of a first die, thereby creating a coated die;
forming a layer of material at least in a gap between the coated die and a second die; and
performing a die stacking operating involving the coated die.

10. The method of claim 9, wherein the first die is a first singulated die, the second die is a second singulated die, and forming the conformal film of insulating material on one or more sides of the first die comprises forming the conformal film of insulating material on one or more sides of the first singulated die.

11. The method of claim 9, wherein the conformal film of insulating material is formed on the one or more sides of the first die via a plasma deposition process.

12. The method of claim 11, wherein forming the conformal film via the plasma deposition process includes exposing the first die to a plasma of one or more gases including O2, N2, or NH3.

13. The method of claim 12, wherein forming the conformal film of insulating material on the one or more sides of the first die comprises:
during the plasma deposition process, controlling a flow direction of a plasma relative to respective surfaces of the opposing sides of the first die.

14. The method of claim 9, wherein forming the layer of material at least in the gap between the coated die and the second die includes forming a first portion of the layer of material in the gap and forming a second portion of the layer of material on a surface of the coated die, and wherein the method further comprises removing at least a portion of the conformal film of insulating material and the second portion of the layer of material from the surface of the coated die, thereby exposing the surface of the coated die.

15. The method of claim 14, wherein performing the die stacking operation includes bonding a third die to the exposed surface of the coated die.

16. The method of claim 14, wherein the coated die and the second die are bonded to a surface of a first carrier, and wherein performing the die stacking operation includes:
aligning a surface of a second carrier with respect to the surface of the first carrier; and
bonding the aligned surfaces of the first and second carriers, wherein a third die is bonded to the surface of the second carrier, and wherein bonding the aligned surfaces of the first and second carriers includes bonding the third die to the exposed surface of the coated die.

17. The method of claim 16, further comprising singulating a stacked die including the coated die and the third die.

18. The method of claim 9, wherein forming the layer of material at least in the gap between the coated die and the second die comprises forming the layer of material on and/or surrounding the conformal film of insulating material.

19. A computer system comprising:
a printed circuit board;
a stacked die disposed on the printed circuit board, the stacked die comprising:
a first die;
a conformal film of insulating material on one or more sides of the first die;
a layer of insulating material on and/or surrounding the conformal film of insulating material; and
a second die bonded to the first die; and
an integrated circuit disposed on the printed circuit board, wherein the stacked die and the integrated circuit are communicatively coupled via the printed circuit board.

20. The system of claim 19, further comprising at least one memory storing one or more instructions and/or at least one processor configured to execute the one or more instructions to cause a computer system to perform one or more operations, wherein the at least one memory or the at least one processor comprises the stacked die.
